(19) United States
(12) Patent Application Publication
(10) Pub. No.: US 2026/0276747 A1
(43) Pub. Date: Sep. 17, 2026

(54) MAGNETIC SENSOR AND MAGNETIC RECORDING DEVICE

(71) Applicants: Kabushiki Kaisha Toshiba, Kawasaki-shi (JP); Toshiba Electronic Devices & Storage Corporation, Kawasaki-shi (JP)

(72) Inventors: Junki Numata, Kawasaki Kanagawa (JP); Yuji Nakagawa, Kawasaki Kanagawa (JP); Masayuki Takagishi, Kunitachi Tokyo (JP); Naoyuki Narita, Funabashi Chiba (JP); Tomoyuki Maeda, Kawasaki Kanagawa (JP)

(21) Appl. No.: 19/532,508

(22) Filed: Feb. 6, 2026

(30) Foreign Application Priority Data
Mar. 11, 2025 (JP) 2025-038344

(51) Int. Cl. G01R 33/07

(52) U.S. Cl. CPC G01R 33/07

(57) ABSTRACT

According to one embodiment, a magnetic sensor includes first, second, third, and fourth conductive portions, a sensor portion, and a controller. A second direction from the third conductive portion to the fourth conductive portion crosses a first direction from the first conductive portion to the second conductive portion. The sensor portion is provided between the first and second conductive portions and between the third and fourth conductive portions. The sensor portion includes a first magnetic member and a first non-magnetic member. The first non-magnetic member is provided between the third conductive portion and the first magnetic member. The controller is configured to supply a first current between the first conductive portion and the second conductive portion and to detect a first signal generated between the first conductive portion and the second conductive portion and a second signal generated between the third conductive portion and the fourth conductive portion.

### CROSS-REFERENCE TO RELATED APPLICATIONS

This application is based upon and claims the benefit of priority from Japanese Patent Application No. 2025-038344, filed on Mar. 11, 2025; the entire contents of which are incorporated herein by reference.

### FIELD

Embodiments described herein relate generally to a magnetic sensor and a magnetic recording device.

### BACKGROUND

A magnetic head including a magnetic sensor is used to reproduce information recorded on a magnetic recording medium such as a hard disk drive (HDD). Improved characteristics of the magnetic sensor are desired.

### BRIEF DESCRIPTION OF THE DRAWINGS

FIG. 1 is a schematic diagram illustrating a magnetic sensor according to a first embodiment;

FIGS. 2A to 2C are schematic diagrams illustrating the operation of the magnetic sensor according to the first embodiment;

FIGS. 3A to 3C are schematic diagrams illustrating the operation of the magnetic sensor according to the first embodiment;

FIG. 4 is a schematic diagram illustrating a magnetic sensor according to the first embodiment;

FIG. 5 is a schematic diagram illustrating a part of the magnetic sensor according to the first embodiment;

FIG. 6 is a schematic cross-sectional view illustrating an application of the magnetic sensor according to the first embodiment;

FIG. 7 is a schematic perspective view illustrating a magnetic recording device according to an embodiment;

FIG. 8 is a schematic perspective view illustrating the magnetic recording device according to an embodiment;

FIG. 9 is a schematic perspective view illustrating a part of a magnetic recording device according to an embodiment;

FIG. 10 is a schematic perspective view illustrating the magnetic recording device according to the embodiment; and

FIGS. 11A and 11B are schematic perspective views illustrating a part of the magnetic recording device according to the embodiment.

### DETAILED DESCRIPTION

According to one embodiment, a magnetic sensor includes a first conductive portion, a second conductive portion, a third conductive portion, a fourth conductive portion, a sensor portion, and a controller. A second direction from the third conductive portion to the fourth conductive portion crosses a first direction from the first conductive portion to the second conductive portion. The sensor portion is provided between the first conductive portion and the second conductive portion and between the third conductive portion and the fourth conductive portion. The sensor portion includes a first magnetic member and a first non-magnetic member. The first non-magnetic member is provided between the third conductive portion and the first magnetic member. The controller is configured to supply a first current between the first conductive portion and the second conductive portion and to detect a first signal generated between the first conductive portion and the second conductive portion and a second signal generated between the third conductive portion and the fourth conductive portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

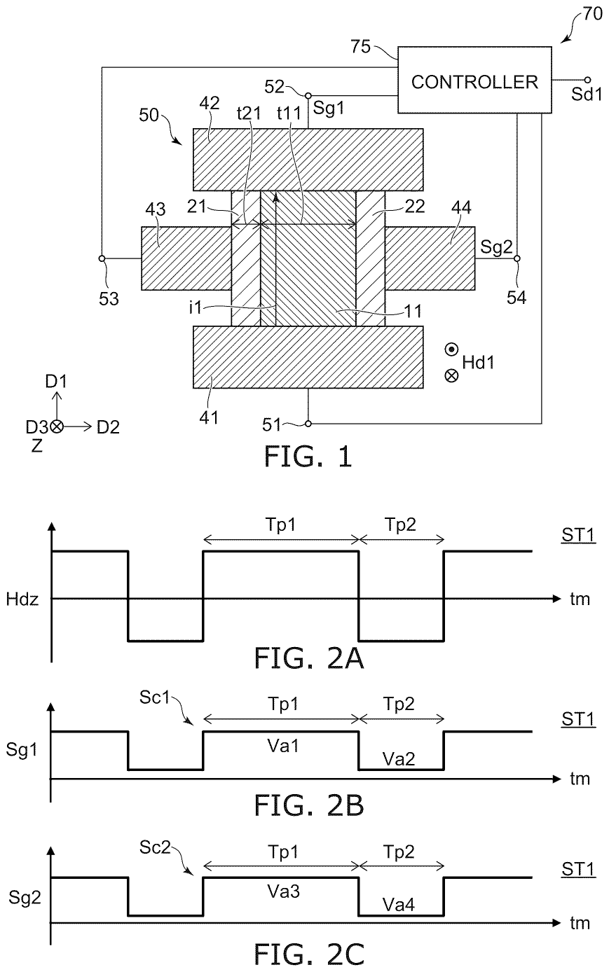

FIG. 1 is a schematic diagram illustrating a magnetic sensor according to the first embodiment.

As shown in FIG. 1, a magnetic sensor 70 according to the embodiment includes a first conductive portion 41, a second conductive portion 42, a third conductive portion 43, a fourth conductive portion 44, a sensor portion 50, and a controller 75.

A second direction D2 from the third conductive portion 43 to the fourth conductive portion 44 crosses a first direction D1 from the first conductive portion 41 to the second conductive portion 42. The second direction D2 may be perpendicular to the first direction D1.

The sensor portion 50 is provided between the first conductive portion 41 and the second conductive portion 42, and between the third conductive portion 43 and the fourth conductive portion 44. The sensor portion 50 includes a first magnetic member 11 and a first non-magnetic member 21. The first non-magnetic member 21 is provided between the third conductive portion 43 and the first magnetic member 11.

In one example, the first magnetic member 11 includes at least one selected from the group consisting of Co₂MnGa, Co₂MnAl, FePt, MnGa, Mn₃Sn, Mn₃Ge, Mn3Ga, RuO₂, MnTe, CrSb, FeSb₂, KRu₄O₈, and Mn₅Si₃. In one example, the first non-magnetic member includes at least one selected from the group consisting of Pt, Au, Ag, Cu, W, Ta, Hf, Nb, Mo, Bi, Al, Pd, Ru, Ir, and Rh.

The controller 75 is electrically connected to the first conductive portion 41, the second conductive portion 42, the third conductive portion 43, and the fourth conductive portion 44. For example, the sensor portion 50 includes a first terminal 51, a second terminal 52, a third terminal 53, and a fourth terminal 54. The first terminal 51 is electrically connected to the first conductive portion 41. The second terminal 52 is electrically connected to the second conductive portion 42. The third terminal 53 is electrically connected to the third conductive portion 43. The fourth terminal 54 is electrically connected to the fourth conductive portion 44.

The controller 75 is configured to supply a first current i1 between the first conductive portion 41 and the second conductive portion 42. The controller 75 is configured to detect a first signal Sg1 generated between the first conductive portion 41 and the second conductive portion 42, and a second signal Sg2 generated between the third conductive portion 43 and the fourth conductive portion 44.

The first signal Sg1 and the second signal Sg2 change in response to a target magnetic field Hd1. For example, the first signal Sg1 and the second signal Sg2 change in response to a component of the target magnetic field Hd1 in the third direction D3. The third direction D3 crosses a plane including the first direction D1 and the second direction D2.

The third direction D3 is defined as a Z-axis direction. A direction perpendicular to the Z-axis direction is defined as an X-axis direction. A direction perpendicular to the Z-axis direction and the X-axis direction is defined as a Y-axis direction. The first direction D1 may be one direction along the X-Y plane. The second direction D2 may be another direction along the X-Y plane.

FIGS. 2A to 2C are schematic diagrams illustrating the operation of the magnetic sensor according to the first embodiment.

The horizontal axis in these diagrams is time tm. The vertical axis in FIG. 2A is a component Hdz along the third direction D3 of the target magnetic field Hd1. The vertical axis in FIG. 2B is the first signal Sg1. The vertical axis in FIG. 2C is the second signal Sg2.

As shown in FIG. 2A, the component Hdz along the third direction D3 of the target magnetic field Hd1 changes. For example, the polarity of the component Hdz changes in response to a change in the orientation of the target magnetic field Hd1.

As shown in FIG. 2B, the first signal Sg1 changes in conjunction with the change in the component Hdz. The first signal Sg1 may include a DC component and a fluctuating component (first fluctuating component Sc1). The first fluctuating component Sc1 has a first value Va1 in a first period Tp1 and a second value Va2 in a second period Tp2. In this example, the first value Va1 is greater than the second value Va2.

As shown in FIG. 2C, the second signal Sg2 changes in conjunction with the change in the component Hdz. The second signal Sg2 may include a DC component and a fluctuating component (second fluctuating component Sc2). The second fluctuating component Sc2 has a third value Va3 in the first period Tp1 and a fourth value Va4 in the second period Tp2. In this example, the third value Va3 is greater than the fourth value Va4.

As described above, the first signal Sg1 changes in response to the target magnetic field Hd1. The change in the first signal Sg1 is considered to be due to, for example, an action of the component Hdz of the target magnetic field Hd1 in the third direction D3 and the first current i1 occurring in the sensor portion 50 including the first magnetic member 11 and the first non-magnetic member 21. For example, the first signal Sg1 is considered to reflect the “magnetic spin Hall effect.”

As described above, the second signal Sg2 changes in response to the target magnetic field Hd1. The change in the second signal Sg2 is considered to be due to, for example, the action of the component Hdz of the target magnetic field Hd1 in the third direction D3 occurring in the sensor portion 50. For example, the second signal Sg2 is considered to reflect the “anomalous Hall effect.”

In the embodiment, the target magnetic field Hd1 is detected based on these signals. By using two signals, the target magnetic field Hd1 can be detected with high sensitivity and high accuracy. According to the embodiment, a magnetic sensor with improved characteristics can be provided.

The controller 75 may be configured to output a detection signal Sd1 obtained by processing the first signal Sg1 and the second signal Sg2.

The magnitude relationship (polarity) of the change in the first signal Sg1 relative to the change in the target magnetic field Hd1 depends, for example, on the material of the sensor portion 50 and the orientation of the first current i1. The magnitude relationship (polarity) of the change in the second signal Sg2 relative to the change in the target magnetic field Hd1 depends, for example, on the material of the sensor portion 50 and the orientation of the first current i1.

In a first state ST1 illustrated in FIGS. 2A to 2C, the first value Va1 is greater than the second value Va2, and the third value Va3 is greater than the fourth value Va4. In this case, the detection signal Sd1 corresponds to the sum of the first changing component Sc1 and the second changing component Sc2. For example, the controller 75 derives a sum of the first changing component Sc1 and the second changing component Sc2, and outputs the obtained result as the detection signal Sd1. The above sum may include a sum of the result of processing the first changing component Sc1 and the result of processing the second changing component Sc2. For example, the controller 75 derives the sum of the result of processing the first changing component Sc1 and the result of processing the second changing component Sc2, and outputs the obtained result as the detection signal Sd1. The processing may include various types of processing, such as amplification, noise removal, and AD conversion.

In one example of the first state ST1, for example, the first magnetic member 11 includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃. In one example of the first state ST1, the first non-magnetic member 21 includes at least one selected from the group consisting of Pt, Au, Ag, and Cu. In another example of the first state ST1, the first non-magnetic member 21 may include Bi. The first non-magnetic member 21 may include, for example, an alloy including Bi. The first non-magnetic member 21 may include, for example, an alloy including Bi and Sb.

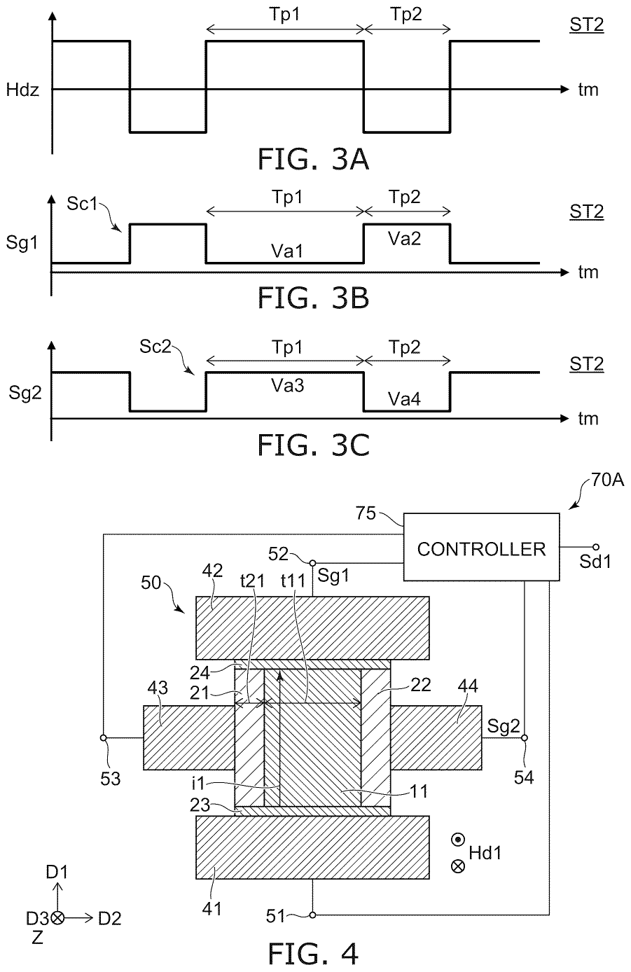

FIGS. 3A to 3C are schematic diagrams illustrating the operation of the magnetic sensor according to the first embodiment.

The horizontal axis of these diagrams is time tm. The vertical axis of FIG. 3A is the component Hdz of the target magnetic field Hd1 along the third direction D3. The vertical axis of FIG. 3B is the first signal Sg1. The vertical axis of FIG. 3C is the second signal Sg2. These diagrams illustrate the second state ST2.

As shown in FIG. 3B, the first changing component Sc1 of the first signal Sg1 has the first value Va1 in the first period Tp1 and the second value Va2 in the second period Tp2. In this example, the first value Va1 is smaller than the second value Va2.

As shown in FIG. 3C, the second changing component Sc2 of the second signal Sg2 has the third value Va3 in the first period Tp1 and the fourth value Va4 in the second period Tp2. In this example, the third value Va3 is greater than the fourth value Va4.

Thus, in the second state ST2, the relationship (polarity) of the magnitude of the change in the second signal Sg2 is opposite to the relationship (polarity) of the magnitude of the change in the first signal Sg1. In this case, the detection signal Sd1 corresponds to the difference between the first changing component Sc1 and the second changing component Sc2. For example, the controller 75 derives a difference between the first changing component Sc1 and the second changing component Sc2, and outputs the obtained result as the detection signal Sd1. The above difference may include the difference between the result of processing the first changing component Sc1 and the result of processing the second changing component Sc2. For example, the controller 75 derives the difference between the result of processing the first changing component Sc1 and the result of processing the second changing component Sc2, and outputs the obtained result as the detection signal Sd1. The processing may include various types of processing, such as amplification, noise removal, and AD conversion.

In one example of the second state ST2, the first magnetic member 11 includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃. In one example of the second state ST2, the first non-magnetic member 21 includes at least one selected from the group consisting of W, Ta, Hf, Nb, and Mo. In another example of the second state ST2, the first non-magnetic member 21 may include Bi. The first non-magnetic member 21 may include, for example, an alloy including Bi. The first non-magnetic member 21 may include, for example, an alloy including Bi and Sb.

In the embodiment, the first non-magnetic member 21 is electrically connected to the third conductive portion 43 and the first magnetic member 11. The first magnetic member 11 is electrically connected to the fourth conductive portion 44.

As shown in FIG. 1, a thickness of the first magnetic member 11 along the second direction D2 is defined as a first magnetic member thickness t11. A thickness of the first non-magnetic member 21 along the second direction D2 is defined as a first non-magnetic member thickness t21. For example, the first magnetic member thickness t11 may be thicker than the first non-magnetic member thickness t21. High sensitivity is easily obtained.

The first magnetic member thickness t11 may be, for example, not less than 1 nm and not more than 25 nm. The first non-magnetic member thickness t21 may be, for example, not less than 0.5 nm and not more than 5 nm. A length of the first magnetic member 11 along the first direction D1 may be, for example, not less than 5 nm and not more than 25 nm.

As shown in FIG. 1, the sensor portion 50 may further include a second non-magnetic member 22. The second non-magnetic member 22 is provided between the first magnetic member 11 and the fourth conductive portion 44. The second non-magnetic member 22 is electrically connected to the first magnetic member 11 and the fourth conductive portion 44. The material of the second non-magnetic member 22 may be the same as the material of the first non-magnetic member 21.

At least one of the first non-magnetic member 21 or the second non-magnetic member 22 may be in contact with the first conductive portion 41. At least one of the first non-magnetic member 21 and the second non-magnetic member 22 may be in contact with the second conductive portion 42. At least one of the first non-magnetic member 21 or the second non-magnetic member 22 may be separated from the first conductive portion 41. At least one of the first non-magnetic member 21 or the second non-magnetic member 22 may be separated from the second conductive portion 42.

The first conductive portion 41, the second conductive portion 42, the third conductive portion 43, and the fourth conductive portion 44 may function, for example, as a shield. Noise is suppressed. The first conductive portion 41, the second conductive portion 42, the third conductive portion 43, and the fourth conductive portion 44 may include, for example, at least one selected from the group consisting of Ni and Fe. A good shielding effect is obtained.

FIG. 4 is a schematic diagram illustrating the magnetic sensor according to the first embodiment.

As shown in FIG. 4, in the magnetic sensor 70A according to the embodiment, the sensor portion 50 further includes a third non-magnetic member 23. The sensor portion 50 may further include a fourth non-magnetic member 24. The configuration of the magnetic sensor 70A except for these may be the same as the configuration of the magnetic sensor 70.

The third non-magnetic member 23 is between the first conductive portion 41 and the first magnetic member 11. The fourth non-magnetic member 24 is between the first magnetic member 11 and the second conductive portion 42. By providing the third non-magnetic member 23, for example, the interaction between the first magnetic member 11 and the first conductive portion 41 is reduced. By providing the fourth non-magnetic member 24, for example, the interaction between the first magnetic member 11 and the second conductive portion 42 is reduced. Higher sensitivity is obtained.

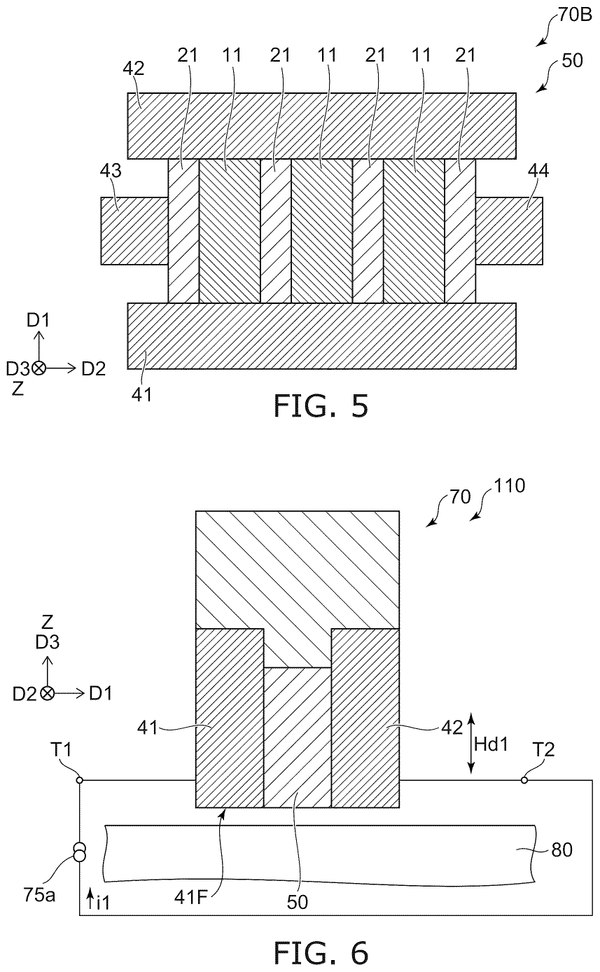

FIG. 5 is a schematic diagram illustrating a part of the magnetic sensor according to the first embodiment.

FIG. 5 illustrates the sensor portion 50 in a magnetic sensor 70B according to the embodiment. In the magnetic sensor 70B, the sensor portion 50 includes a plurality of first magnetic members 11 and a plurality of first non-magnetic members 21. The configuration of the magnetic sensor 70B except for this may be similar to the configuration the magnetic sensor 70.

As shown in FIG. 5, in the magnetic sensor 70B, the sensor portion 50 includes the plurality of first magnetic members 11 and the plurality of first non-magnetic members 21. One of the plurality of first magnetic members 11 is between one of the plurality of first non-magnetic members 21 and another one of the plurality of first non-magnetic members 21 in the second direction D2. One of the plurality of first non-magnetic members 21 is between one of the plurality of first magnetic members 11 and another one of the plurality of first magnetic members 11 in the second direction D2. One of the plurality of first magnetic members 11 contacts two of the plurality of first non-magnetic members 21.

In this magnetic sensor 70B, the target magnetic field Hd1 is detected based on the first signal Sg1 and the second signal Sg2. A structure including multiple layers enables detection with higher sensitivity and higher accuracy. A magnetic sensor with improved characteristics can be provided.

A part of one of the plurality of first magnetic members 11 may be continuous with a part of another one of the plurality of first magnetic members 11. The position at which a part of one of the plurality of first magnetic members 11 is continuous with a part of another one of the plurality of first magnetic members 11 may be arbitrary.

FIG. 6 is a schematic cross-sectional view illustrating an application of the magnetic sensor according to the first embodiment.

As shown in FIG. 6, the magnetic sensor 70 (or magnetic sensor 70A) may be applied to a magnetic head 110. A direction from the magnetic recording medium 80 to the magnetic head 110 may be along the third direction D3. For example, the controller 75 may include a current source 75a provided between the first conductive portion 41 and the second conductive portion 42. The magnetic field from the magnetic recording medium 80 corresponds to the target magnetic field Hd1. The magnetic recording medium 80 moves relative to the magnetic head 110 in a plane crossing the third direction D3.

### Second Embodiment

The second embodiment relates to a magnetic recording device.

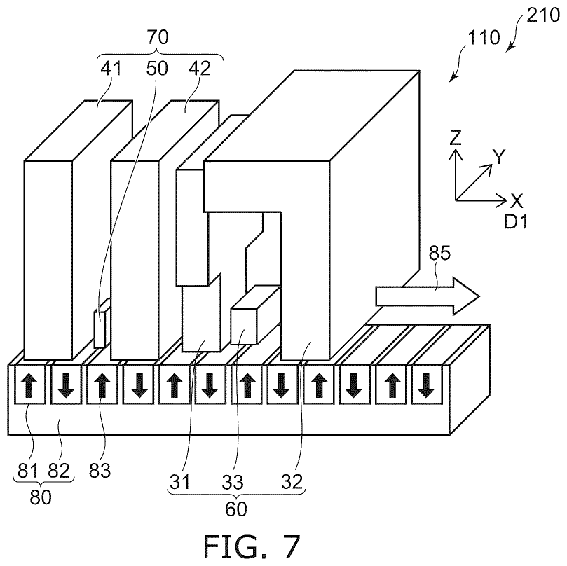

FIG. 7 is a schematic perspective view illustrating a magnetic recording device according to the embodiment.

As shown in FIG. 7, a magnetic recording device 210 according to the embodiment includes the magnetic head 110, the magnetic sensor 70 (or magnetic sensor 70A) according to the first embodiment, and the magnetic recording medium 80. The target magnetic field Hd1 corresponds to information recorded on the magnetic recording medium 80. The magnetic sensor 70 corresponds to a reproducing section.

The magnetic head 110 may include a recording section 60. The recording section 60 records information on the magnetic recording medium 80. The magnetic sensor 70 reproduces the information recorded on the magnetic recording medium 80.

The magnetic recording medium 80 includes, for example, a medium substrate 82 and a magnetic recording layer 81 provided on the medium substrate 82. The magnetization 83 of the magnetic recording layer 81 is controlled by the recording section 60. The recording section 60 includes, for example, a first magnetic pole 31 and a second magnetic pole 32. The first magnetic pole 31 is, for example, a main magnetic pole. The second magnetic pole 32 is, for example, a trailing shield. The recording section 60 may include a recording element 33. The recording element 33 may include a magnetic field control element or a high-frequency oscillation element. The recording element 33 may be omitted.

As shown in FIG. 7, the magnetic recording medium 80 moves relative to the magnetic head 110 in the medium movement direction 85. The magnetic head 110 controls information corresponding to the magnetization 83 of the magnetic recording layer 81 at any position. The magnetic head 110 reproduces information corresponding to the magnetization 83 of the magnetic recording layer 81 at any position.

In this example, the first direction D1 from the first conductive portion 41 to the second conductive portion 42 is along the X-axis direction. The X-axis direction is along the down-track direction. In FIG. 7, the third conductive portion 43 and the fourth conductive portion 44 are omitted.

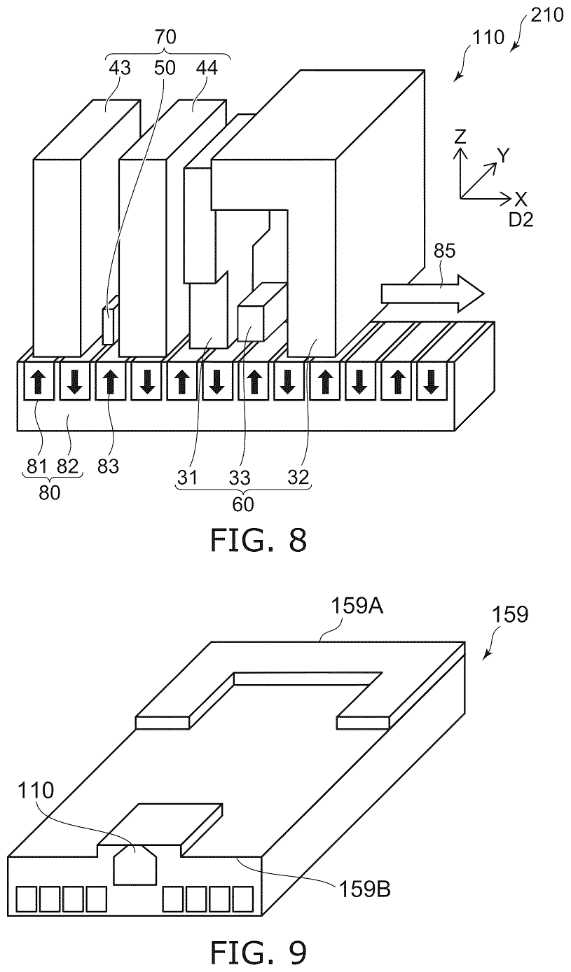

FIG. 8 is a schematic perspective view illustrating the magnetic recording device according to an embodiment.

In the example shown in FIG. 8, the second direction D2 from the third conductive portion 43 to the fourth conductive portion 44 is along the X-axis direction. The X-axis direction is along the down-track direction. In FIG. 8, the first conductive portion 41 and the second conductive portion 42 are omitted.

FIG. 9 is a schematic perspective view illustrating a part of a magnetic recording device according to an embodiment.

FIG. 9 illustrates a head slider.

The magnetic head 110 is provided on a head slider 159. The head slider 159 includes, for example, Al₂O₃/TiC. The head slider 159 moves relative to the magnetic recording medium while floating above or in contact with the magnetic recording medium.

The head slider 159 has, for example, an air inflow side 159A and an air outflow side 159B. The magnetic head 110 is disposed on the side of the air outflow side 159B of the head slider 159. As a result, the magnetic head 110 moves relative to the magnetic recording medium while floating above or in contact with the magnetic recording medium.

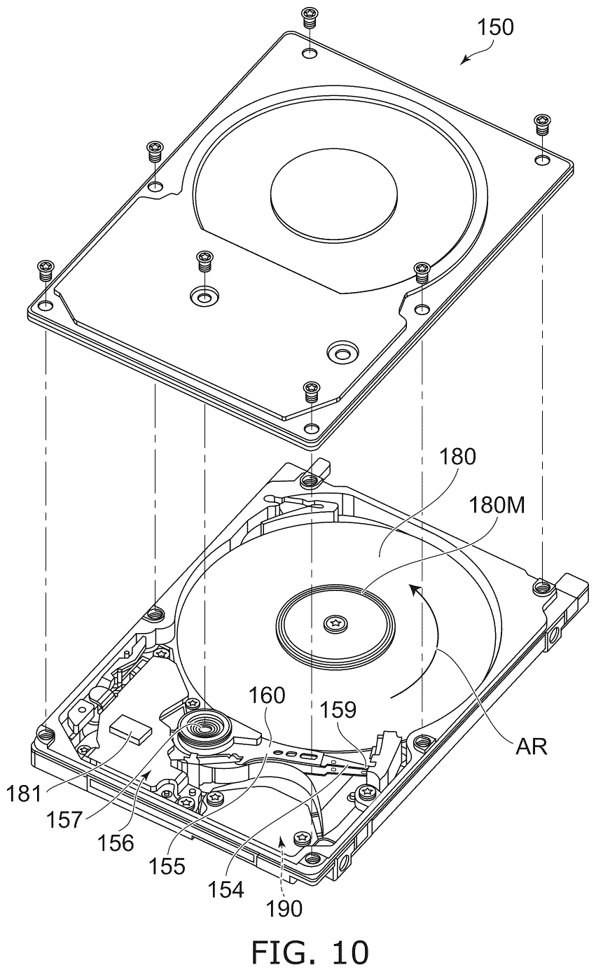

FIG. 10 is a schematic perspective view illustrating the magnetic recording device according to the embodiment.

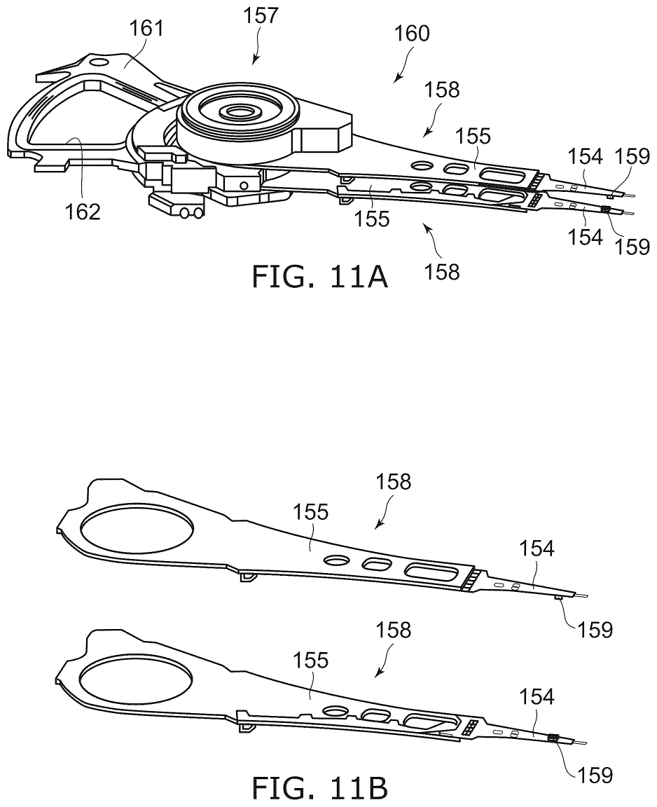

FIGS. 11A and 11B are schematic perspective views illustrating a part of the magnetic recording device according to the embodiment.

As shown in FIG. 10, in a magnetic recording device 150 according to the embodiment, a rotary actuator is used. The recording medium disk 180 is connected to a spindle motor 180M. The recording medium disk 180 is rotated in a direction of arrow AR by the spindle motor 180M. The spindle motor 180M is responsive to control signals from the drive device controller. The magnetic recording device 150 according to the embodiment may include the plurality of recording medium disks 180. The magnetic recording device 150 may include a recording medium 181. The recording medium 181 is, for example, an SSD (Solid State Drive). A non-volatile memory such as a flash memory is used for the recording medium 181, for example. For example, the magnetic recording device 150 may be a hybrid HDD (Hard Disk Drive).

The head slider 159 records and reproduces information to be recorded on the recording medium disk 180. The head slider 159 is provided at an end of a thin-film suspension 154. A magnetic head according to the embodiment is provided near the end of the head slider 159.

While the recording medium disk 180 is rotating, the pressing pressure by the suspension 154 and the floating pressure generated at the medium facing face (ABS) of the head slider 159 are balanced. The distance between the medium facing face of the head slider 159 and the surface of the recording medium disk 180 is the predetermined fly height. In the embodiment, the head slider 159 may contact the recording medium disk 180. For example, a contact sliding type may be applied.

The suspension 154 is connected to one end of an arm 155 (e.g., an actuator arm). The arm 155 includes, for example, a bobbin part or the like. The bobbin part holds a drive coil. A voice coil motor 156 is provided at the other end of the arm 155. The voice coil motor 156 is a type of linear motor. The voice coil motor 156 includes, for example, a drive coil and a magnetic circuit. The drive coil is wound on the bobbin part of the arm 155. The magnetic circuit includes permanent magnets and opposing yokes. The drive coil is provided between the permanent magnet and the opposing yoke. The suspension 154 includes one end and the other end. The magnetic head is provided at one end of the suspension 154. The arm 155 is connected to the other end of the suspension 154.

The arm 155 is held by ball bearings. Ball bearings are provided at two locations above and below a bearing part 157. The arm 155 can be rotated and slid by the voice coil motor 156. The magnetic head can move to any position on the recording medium disk 180.

FIG. 11A is an enlarged perspective view of the head stacked body assembly 160, illustrating the configuration of a part of the magnetic recording device.

FIG. 11B is a perspective view illustrating the magnetic head assembly (head gimbal assembly: HGA) 158 that forms part of the head stacked body assembly 160.

As shown in FIG. 11A, the head stacked body assembly 160 includes the bearing part 157, the magnetic head assembly 158 and a support frame 161. The magnetic head assembly 158 extends from the bearing part 157. The support frame 161 extends from the bearing part 157. A direction in which the support frame 161 extends is opposite to a direction in which the magnetic head assembly 158 extends. The support frame 161 supports a coil 162 of the voice coil motor 156.

As shown in FIG. 11B, the magnetic head assembly 158 includes the arm 155 extending from the bearing part 157 and the suspension 154 extending from the arm 155.

The head slider 159 is provided at the end of the suspension 154. The head slider 159 is provided with the magnetic head according to the embodiment.

The magnetic head assembly 158 (head gimbal assembly) according to the embodiment includes the magnetic head according to the embodiment, the head slider 159 provided with the magnetic head, the suspension 154 and the arm 155. The head slider 159 is provided at one end of the suspension 154. The arm 155 is connected to the other end of the suspension 154.

The suspension 154 may include, for example, a wiring (not shown) for recording and reproducing signals. The suspension 154 may include, for example, a heater wiring (not shown) for adjusting the fly height. The suspension 154 may include a wiring (not shown) for, for example, an oscillator element or the like. These wires may be electrically connected to a plurality of electrodes provided on the magnetic head.

A signal processor 190 is provided in the magnetic recording device 150. The signal processor 190 uses a magnetic head to record and reproduce signals on a magnetic recording medium. Input/output lines of the signal processor 190 are connected to, for example, electrode pads of the magnetic head assembly 158 and electrically connected to the magnetic head.

The magnetic recording device 150 according to the embodiment includes the magnetic recording medium, the magnetic head according to the embodiment, a movable part, a position controller, and a signal processor. The movable part separates the magnetic recording medium from the magnetic head or makes them relatively movable while they are in contact with each other. The position controller aligns the magnetic head with a predetermined recording position on the magnetic recording medium. The signal processor records and reproduces signals on the magnetic recording medium using the magnetic head.

For example, the recording medium disk 180 is used as the above magnetic recording medium. The movable part includes, for example, the head slider 159. The position controller described above includes, for example, the magnetic head assembly 158.

The embodiments may include the following Technical proposals:

### Technical Proposal 1

A magnetic sensor, comprising:
a first conductive portion;
a second conductive portion;
a third conductive portion;
a fourth conductive portion, a second direction from the third conductive portion to the fourth conductive portion crossing a first direction from the first conductive portion to the second conductive portion;
a sensor portion provided between the first conductive portion and the second conductive portion and between the third conductive portion and the fourth conductive portion, the sensor portion including a first magnetic member and a first non-magnetic member, the first non-magnetic member being provided between the third conductive portion and the first magnetic member; and
a controller,
the controller being configured to supply a first current between the first conductive portion and the second conductive portion and to detect a first signal generated between the first conductive portion and the second conductive portion and a second signal generated between the third conductive portion and the fourth conductive portion.

### Technical Proposal 2

The magnetic sensor according to Technical proposal 1, wherein
the first signal and the second signal change in response to a target magnetic field.

### Technical Proposal 3

The magnetic sensor according to Technical proposal 1, wherein
the first signal and the second signal change in response to a component of a target magnetic field in a third direction, and
the third direction crosses a plane including the first direction and the second direction.

### Technical Proposal 4

The magnetic sensor according to Technical proposal 3, wherein
the controller is configured to output a detection signal obtained by processing the first signal and the second signal.

### Technical Proposal 5

The magnetic sensor according to Technical proposal 4, wherein
a first changing component of the first signal is a first value in a first period and a second value in a second period,
the first value is greater than the second value,
a second changing component of the second signal is a third value in the first period and a fourth value in the second period,
the third value is greater than the fourth value, and
the detection signal corresponds to a sum of the first changing component and the second changing component.

### Technical Proposal 6

The magnetic sensor according to Technical proposal 5, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, Au, Ag, and Cu.

### Technical Proposal 7

The magnetic sensor according to Technical proposal 4, wherein
a first changing component of the first signal is a first value in a first period and a second value in a second period,
the first value is smaller than the second value,
a second changing component of the second signal is a third value in the first period and a fourth value in the second period,
the third value is larger than the fourth value,
the detection signal corresponds to a difference between the first changing component and the second changing component.

### Technical Proposal 8

The magnetic sensor according to Technical proposal 7, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of W, Ta, Hf, Nb, and Mo.

### Technical Proposal 9

The magnetic sensor according to Technical proposal 3, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, Au, Ag, Cu, W, Ta, Hf, Nb, Mo, Bi, Al, Pd, Ru, Ir, and Rh.

### Technical Proposal 10

The magnetic sensor according to any one of Technical proposals 3-9, wherein
the first non-magnetic member is electrically connected to the third conductive portion and the first magnetic member, and
the first magnetic member is electrically connected to the fourth conductive portion.

### Technical Proposal 11

The magnetic sensor according to any one of Technical proposals 3-10, wherein
a thickness of the first magnetic member along the second direction of the first magnetic member is thicker than a thickness of the first non-magnetic member along the second direction of the first non-magnetic member.

### Technical Proposal 12

The magnetic sensor according to any one of Technical proposals 3-10, wherein
a thickness of the first magnetic member along the second direction of the first magnetic member is not less than 1 nm and not more than 25 nm, and
a thickness of the first non-magnetic member along the second direction of the first non-magnetic member is not less than 0.5 nm and not more than 5 nm.

### Technical Proposal 13

The magnetic sensor according to any one of Technical proposals 3-12, wherein
the first conductive portion, the second conductive portion, the third conductive portion, and the fourth conductive portion function as a shield.

### Technical Proposal 14

The magnetic sensor according to any one of Technical proposals 3 to 13, wherein
the sensor portion further includes a second non-magnetic member,
the second non-magnetic member is provided between the first magnetic member and the fourth conductive portion, and
the second non-magnetic member is electrically connected to the first magnetic member and the fourth conductive portion.

### Technical Proposal 15

The magnetic sensor according to any one of Technical proposals 3-13, wherein
the sensor portion includes a plurality of the first magnetic members and a plurality of the first non-magnetic members, and
one of the plurality of the first magnetic members is between one of the plurality of the first non-magnetic members and another one of the plurality of the first non-magnetic members in the second direction.

### Technical Proposal 16

The magnetic sensor according to any one of Technical proposals 3-15, wherein
the sensor section further includes a third non-magnetic member, and
the third non-magnetic member is between the first conductive section and the first magnetic member 11.

### Technical Proposal 17

A magnetic recording device, comprising:
a magnetic head including a magnetic sensor according to any one of Technical proposals 3-13; and
a magnetic recording medium,
the target magnetic field corresponds to information recorded on the magnetic recording medium.

### Technical Proposal 18

The magnetic recording device according to Technical proposal 17, wherein
a direction from the magnetic recording medium to the magnetic sensor is along the third direction.

### Technical Proposal 19

The magnetic recording device according to Technical proposal 18, wherein
the first direction is along a down-track direction of the magnetic recording medium.

### Technical Proposal 20

The magnetic recording device according to Technical proposal 18, wherein
the second direction is along a down-track direction of the magnetic recording medium.

According to the embodiment, a magnetic sensor and a magnetic recording device can be provided that can improve the characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in magnetic sensors and magnetic recording devices such as conductive portions, magnetic members, non-magnetic members, magnetic recording mediums, magnetic heads, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all magnetic heads and all magnetic sensors and all magnetic recording devices practicable by an appropriate design modification by one skilled in the art based on the magnetic sensors and the magnetic recording devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A magnetic sensor, comprising:
a first conductive portion;
a second conductive portion;
a third conductive portion;
a fourth conductive portion, a second direction from the third conductive portion to the fourth conductive portion crossing a first direction from the first conductive portion to the second conductive portion;
a sensor portion provided between the first conductive portion and the second conductive portion and between the third conductive portion and the fourth conductive portion, the sensor portion including a first magnetic member and a first non-magnetic member, the first non-magnetic member being provided between the third conductive portion and the first magnetic member; and
a controller,
the controller being configured to supply a first current between the first conductive portion and the second conductive portion and to detect a first signal generated between the first conductive portion and the second conductive portion and a second signal generated between the third conductive portion and the fourth conductive portion.

2. The magnetic sensor according to claim 1, wherein
the first signal and the second signal change in response to a target magnetic field.

3. The magnetic sensor according to claim 1, wherein
the first signal and the second signal change in response to a component of a target magnetic field in a third direction, and
the third direction crosses a plane including the first direction and the second direction.

4. The magnetic sensor according to claim 3, wherein
the controller is configured to output a detection signal obtained by processing the first signal and the second signal.

5. The magnetic sensor according to claim 4, wherein
a first changing component of the first signal is a first value in a first period and a second value in a second period,
the first value is greater than the second value,
a second changing component of the second signal is a third value in the first period and a fourth value in the second period,
the third value is greater than the fourth value, and
the detection signal corresponds to a sum of the first changing component and the second changing component.

6. The magnetic sensor according to claim 5, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, Au, Ag, and Cu.

7. The magnetic sensor according to claim 4, wherein
a first changing component of the first signal is a first value in a first period and a second value in a second period,
the first value is smaller than the second value,
a second changing component of the second signal is a third value in the first period and a fourth value in the second period,
the third value is larger than the fourth value,
the detection signal corresponds to a difference between the first changing component and the second changing component.

8. The magnetic sensor according to claim 7, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of W, Ta, Hf, Nb, and Mo.

9. The magnetic sensor according to claim 3, wherein
the first magnetic member includes at least one selected from the group consisting of Co₂MnGa, Co₂MnAl, FePt, MnGa, Mn₃Sn, Mn₃Ge, Mn₃Ga, RuO₂, MnTe, CrSb, FeSb₂, KRu₄O₈, and Mn₅Si₃, and
the first non-magnetic member includes at least one selected from the group consisting of Pt, Au, Ag, Cu, W, Ta, Hf, Nb, Mo, Bi, Al, Pd, Ru, Ir, and Rh.

10. The magnetic sensor according to claim 3, wherein
the first non-magnetic member is electrically connected to the third conductive portion and the first magnetic member, and
the first magnetic member is electrically connected to the fourth conductive portion.

11. The magnetic sensor according to claim 3, wherein
a thickness of the first magnetic member along the second direction of the first magnetic member is thicker than a thickness of the first non-magnetic member along the second direction of the first non-magnetic member.

12. The magnetic sensor according to claim 3, wherein
a thickness of the first magnetic member along the second direction of the first magnetic member is not less than 1 nm and not more than 25 nm, and
a thickness of the first non-magnetic member along the second direction of the first non-magnetic member is not less than 0.5 nm and not more than 5 nm.

13. The magnetic sensor according to claim 3, wherein
the first conductive portion, the second conductive portion, the third conductive portion, and the fourth conductive portion function as a shield.

14. The magnetic sensor according to claim 3, wherein
the sensor portion further includes a second non-magnetic member,
the second non-magnetic member is provided between the first magnetic member and the fourth conductive portion, and
the second non-magnetic member is electrically connected to the first magnetic member and the fourth conductive portion.

15. The magnetic sensor according to claim 3, wherein
the sensor portion includes a plurality of the first magnetic members and a plurality of the first non-magnetic members, and
one of the plurality of the first magnetic members is between one of the plurality of the first non-magnetic members and another one of the plurality of the first non-magnetic members in the second direction.

16. The magnetic sensor according to claim 3, wherein
the sensor section further includes a third non-magnetic member, and
the third non-magnetic member is between the first conductive section and the first magnetic member.

17. A magnetic recording device, comprising:
a magnetic head including a magnetic sensor according to claim 3; and
a magnetic recording medium,
the target magnetic field corresponds to information recorded on the magnetic recording medium.

18. The magnetic recording device according to claim 17, wherein
a direction from the magnetic recording medium to the magnetic sensor is along the third direction.

19. The magnetic recording device according to claim 18, wherein
the first direction is along a down-track direction of the magnetic recording medium.

20. The magnetic recording device according to claim 18, wherein
the second direction is along a down-track direction of the magnetic recording medium.
